(19) United States
(12) Patent Application Publication
(10) Pub. No.: US 2024/0425351 A1
(43) Pub. Date: Dec. 26, 2024

(54) MICROELECTROMECHANICAL DEVICE, MICROELECTROMECHANICAL PRESSURE SENSOR, MICROELECTROMECHANICAL MICROPHONE AND MICROELECTROMECHANICAL COMBINATION SENSOR ELEMENT.

(71) Applicant: Robert Bosch GmbH, Stuttgart (DE)

(72) Inventors: Christoph Schelling, Stuttgart (DE); Jochen Reinmuth, Reutlingen (DE)

(21) Appl. No.: 18/738,435

(22) Filed: Jun. 10, 2024

(30) Foreign Application Priority Data
Jun. 22, 2023 (DE) 10 2023 205 850.2

(51) Int. Cl. B81B 3/00; G01L 9/00

(52) U.S. Cl. CPC B81B 3/0021; G01L 9/0072; B81B 2201/0257; B81B 2201/0264; B81B 2203/0127; B81B 2203/0154; B81B 2203/0315; B81B 2203/04

(57) ABSTRACT

A microelectromechanical device for capacitive fluid pressure measurement. The microelectromechanical device has a first electrode and a second electrode forming a counter-electrode. The device has a cavity formed between a first boundary layer and a second boundary layer or a substrate, in which cavity the first electrode is arranged and movably mounted, wherein the first boundary layer and/or the second boundary layer can be deflected by a fluid pressure and wherein the first boundary layer and/or the second boundary layer is or are coupled to the first electrode by a first coupling element for transmitting a deflection movement to the movably mounted first electrode. A microelectromechanical pressure sensor, a microelectromechanical microphone, and a microelectromechanical combination sensor element, are also disclosed.

### CROSS REFERENCE

The present application claims the benefit under 35 U.S.C. § 11 of German Patent Application No. DE 10 2023 205 850.2 filed on Jun. 22, 2023, which is expressly incorporated herein by reference in its entirety.

### FIELD

The present invention relates to a micromechanical device, also called a MEMS device, a micromechanical pressure sensor, a microelectromechanical microphone and a microelectromechanical combination sensor element.

### BACKGROUND INFORMATION

A microelectromechanical device is described, for example, in U.S. Patent Application Publication No. US 2021/0292158 A1 which describes a MEMS microphone unit with a movable element and a measuring unit arranged in a cavity that is under negative pressure, wherein a movement of the movable element is mechanically transmitted to the measuring unit.

German Patent Application No. DE 10 2021 206 005 A1 describes a micromechanical component for a microphone device with an actuator electrode, a stator electrode and a sensor element which is connected to the actuator electrode by means of a spring or lever structure. The actuator electrode and the stator electrode can be arranged in a sealed cavity.

PCT Patent Application No. WO 2016/200538 A1 relates to an electromechanical device with a movable mirror which is held above a stationary electrode by means of hinges and anchor points.

China Patent Application No. CN 110621612 A describes a MEMS actuator device with a cavity and a movable element that is arranged in the cavity and can be driven via a potential between a first and another electrode.

PCT Patent Application No. WO 2016/067154 A1 describes a MEMS display element with a movable, light-reflecting electrode.

### DETAILED DESCRIPTION OF EXAMPLE EMBODIMENTS

According to an example embodiment of the present invention, a microelectromechanical device for capacitive fluid pressure measurement having a first electrode and a second electrode forming a counter-electrode is provided, wherein the device has a cavity formed between a first boundary layer and a second boundary layer or a substrate and in which the first electrode is arranged and movably mounted, wherein the first boundary layer and/or the second boundary layer can be deflected by a fluid pressure, and wherein the first boundary layer and/or the second boundary layer is or are coupled to the first electrode by a first coupling element for transmitting a deflection movement to the movably mounted first electrode.

As a result, a particularly compact microelectromechanical device can be provided. By coupling a movable boundary layer to an electrode movably arranged in the cavity, a direct transmission of an external deflection movement to the electrode is made possible, the measuring mechanism is integrated into the cavity structures, and the device components are therefore concentrated in a small space protected from environmental influences. Advantageously, this encapsulated structure has no exposed moving components and gaps that could be adversely affected by external influences such as stuck particles and would thus impair the functionality of the components. The structural components of the device that delimit or are arranged within the cavity can be described as cavity structures. The in particular fluid-tight cavity with an integrated measuring mechanism makes possible a very sensitive, particle-insensitive fluid pressure measurement with a very good signal-to-noise ratio and reduced fluidic squeeze-film damping effects. Due to its compact design, the device can be designed to be particularly powerful with the same size or to be particularly small with the same required power. The cavity can have a predetermined gas pressure below ambient air pressure. In this way, thermal noise and squeeze-film damping effects are effectively eliminated. The device can also have a plurality of cavities with first electrodes arranged therein, wherein the cavities can be encapsulated, i.e., each can be sealed fluid-tight.

Depending on the embodiment, the cavity of the device can be formed in a first variant between a first boundary layer and a second boundary layer of the device, or in a second variant between a first boundary layer and a substrate of the device. In the first variant, the first and the second boundary layers can be deflected by a fluid pressure acting on the first or second boundary layer. If the first and the second boundary layers are mechanically coupled to one another, the first and the second boundary layer can be deflected together by a fluid pressure acting on the first boundary layer or on the second boundary layer. In the second variant, a surface of the substrate can at least partially form a boundary of the cavity. The first boundary layer can be deflected by a fluid pressure acting on the first boundary layer.

According to an example embodiment of the present invention, the first and/or the second boundary layer can be formed, for example, by a flexible or elastic membrane or a flexure beam, and can be reversibly deflected by a fluid pressure acting on the boundary layer. The fluid pressure can, for example, be a static, quasi-static or dynamic fluid pressure, for example it can also represent a mechanical fluid pressure oscillation such as a sound oscillation that causes a mechanical oscillation of the boundary layer. The first and/or the second boundary layer can be displaceable, in particular continuously displaceable, between a rest position or starting position and a deflection position. Analogously, the first electrode can be displaceable or tiltable, in particular continuously displaceable or tiltable, between a rest position or starting position and a deflection position. As explained below, the displaceability or tiltability can be understood in particular as a combination of at least partial translational, rotational and/or deformatory movements.

The deflection movement transmitted from the first and/or second boundary layer to the first electrode by means of the first coupling element can be converted into an electrical signal by a resulting change in electrical capacitance between the first electrode and the second electrode forming a counter-electrode so that the device can be referred to as an electromechanical transducer. The first electrode and the counter-electrode can form a measuring capacitor with which relative capacitance changes in relation to an initial capacitance can be detected and evaluated, wherein the capacitance change depends on a relative movement of the first electrode with respect to the second electrode, and this in turn depends on a deflection movement of the boundary layer coupled to the first electrode.

The coupling element can act as a driver for the first electrode. The mechanical coupling of the first electrode to the boundary layer makes possible a synchronous movement of the two components and therefore a direct conversion of the mechanical signal into an electrical signal.

According to an example embodiment of the present invention, the coupling element with which the first electrode is coupled to the first and/or second boundary layer can have a length which substantially corresponds to the distance between the first electrode and the boundary layer, and a width and height or a diameter which extend perpendicular to the length. The coupling element can also have a length that is less than the distance between the first electrode and the boundary layer so that a mechanical support only results when a predefined external pressure value is reached. The coupling element can have a smaller, in particular several times smaller, width and height or diameter compared to the length, so that, for example, a narrow, rod- or strut-shaped coupling element is formed. The coupling element can extend transversely, for example orthogonally to the first electrode and the boundary layer. At the coupling point, the coupling element can cover an electrode area of the first electrode which can be, for example, less than 10%, in particular less than 5% or 2% of the total electrode area. The coupling of the electrode to the boundary layer can therefore basically be a punctiform coupling. The device can also have a plurality of first coupling elements that couple the first electrode to the boundary layer. The coupling elements can in particular be formed from an insulating material so that the boundary layer and the first electrode can be electrically insulated from each other.

The first electrode can have a capacitance measuring section which is substantially opposite to a capacitance measuring section of the second electrode so that the electrical capacitance between the capacitance measuring sections can be acquired. The first electrode and/or the second electrode can have additional sections that face away from the capacitance measuring section. Depending on the embodiment, the coupling element can be arranged, for example, on a capacitance measuring section or away from the capacitance measuring section. The first and/or second electrodes can have perforations in a region facing away from the capacitance measuring section in order to maximize the ratio of the measuring capacitance to the basic capacitance of the arrangement.

According to one example embodiment of the present invention, the second electrode can be arranged in the cavity. As a result, a compact and efficient measuring arrangement can be formed. The second electrode can, for example, be attached to the substrate or to a fixed body structure of the device, or to a lateral cavity boundary, and can project into the cavity. The second electrode can extend substantially parallel to a substrate surface or a substrate plane. The second electrode can extend substantially parallel to the first electrode when the first electrode is in a non-deflected state, for example a rest position. The second electrode extends at a distance from the first electrode to form a measuring capacitor with it. For example, the first and second electrodes can be designed as interdigital electrodes so that the measuring capacitor of the first electrode and of the second electrode arranged in the cavity form a first measuring capacitor from which a 2f signal can be tapped. This advantageously makes it possible to read out a measurement signal at twice the frequency of an excitation frequency. Since noise is usually less at higher frequencies, this results in a better signal-to-noise ratio for the measurement. The doubled measuring frequency can result from an oscillating movement of the movable first electrode around the second electrode during deflections of the boundary layer.

According to one example embodiment of the present invention, the second electrode can be movably mounted, wherein the first boundary layer and/or the second boundary layer is/are coupled to the second electrode by a second coupling element for transmitting a deflection movement to the second electrode. Accordingly, the second electrode can also be movably mounted like the first electrode. This can, for example, make possible a greater relative movement of the electrodes to each other and therefore cause a greater change in capacitance. The second coupling element can be designed similarly or identically to the first coupling element. The type of movable bearing, for example a rotational and/or translational mobility of the first electrode and of the second electrode, makes different movement paths of the electrodes possible and can be adapted to individual requirements and space conditions. For example, one of the two electrodes can be mounted so as to be translationally displaceable at least sectionally, and the other of the two electrodes can be mounted so as to be at least sectionally tiltable about a tilt axis, or both electrodes can be tiltable by different angles by means of lever arms of different lengths. The device can also comprise a plurality of second coupling elements that couple the second electrode to the first and/or second boundary layer.

A movably mounted electrode, for example the first movably mounted electrode and/or the second movably mounted electrode, can have at least one insulating stop. In the event of a strong deflection or overload of the electrode, this can prevent the electrode from welding to or sticking to another structure of the device, for example to the first and/or second boundary layer. Alternatively or additionally, an insulating stop can also be provided on the first and/or second boundary layer. The stop can increase the robustness of the cavity structure against overloading by strengthening the boundary layer in the case of contact and minimizing the contact area.

According to one example embodiment of the present invention, the first coupling element and the second coupling element can be arranged on the first electrode and on the second electrode such that the first electrode and the second electrode are movable in opposite directions to each other. This can cause larger capacitance changes and therefore a stronger measurement signal. For example, both electrodes can be tilted in different directions relative to each other around a tilt axis. For example, the first coupling element can be arranged on the first electrode away from its capacitance measuring section, and the second coupling element on the second electrode on its capacitance measuring section, so that the second coupling element on the second electrode can cause a direct deflection of the capacitance measuring section, and the first coupling element on the first electrode can cause a deflection of the capacitance measuring section via a lever when the tilt axis of the first electrode lies between the capacitance measuring section and the coupling element. This makes it possible to achieve an opposite movement of the electrodes, in particular of their capacitance measuring sections, relative to each other. An opposite movement of the electrodes can, for example, also mean a translational movement towards or away from each other.

The first electrode and/or the second electrode arranged in the cavity can be continuous or segmented. Given a segmented design of the electrode, there can be a plurality of spatially separated electrode sections of the same electrode, or in other words, a plurality of first electrodes and/or a plurality of second electrodes can be arranged in the cavity. This enables more efficient use of the component surface.

According to one example embodiment of the present invention, the second electrode and/or a third electrode can be arranged in or on the first boundary layer and/or in or on the second boundary layer or formed by them. It is therefore possible, for example, to arrange the second electrode not in the cavity of the device but in or on the first and/or the second boundary layer, or to form the second electrode with the first and/or the second boundary layer. In addition, it is possible to arrange the second electrode in the cavity of the device and a third electrode in or on the first and/or the second boundary layer, or to form the third electrode with the first and/or the second boundary layer. The second and third electrodes can each form a counter-electrode to the first electrode. Conceptually, the ordinal numbers are not intended to indicate the number of electrodes, but rather to make possible arrangements of electrodes understandable. The device can therefore also have a plurality of first electrodes, a plurality of second electrodes and/or a plurality of third electrodes. The first electrode is arranged in the cavity of the device. The second electrode can be arranged in the cavity or in or on the first and/or second boundary layer. The third electrode can be arranged in or on the first and/or the second boundary layer when the second electrode is arranged in the cavity. The first electrode and the second or third electrode in or on the first and/or second boundary layer can form a second measuring capacitor from which a 1f signal can be tapped. This allows another or alternative measuring capacitor to be created in addition to the first measuring capacitor. A 1f signal is a measurement signal whose measurement frequency corresponds to the excitation frequency. In particular, in combination with the first measuring capacitor which can be formed by the first electrode and a second electrode in the cavity of the device, a plurality of measuring capacitors can therefore be used in the device, which allows, for example, a differential-capacitive measurement, and generally great flexibility with regard to the measurement signal evaluation. The measurement signals, in particular the if or 2f measurement signal of the first measurement capacitor and the 1f measurement signal of the second measurement capacitor, can be detected simultaneously and reckoned up to form a final measurement signal. Furthermore, with two movable boundary layers, it is possible to provide a counter-electrode in each of the two boundary layers so that more additional measuring capacitors can be formed and detected simultaneously analogous to the above-described embodiment.

According to one example embodiment of the present invention, the first electrode and/or the second electrode can be translationally displaceable at least sectionally by the deflection movement of the first boundary layer and/or the second boundary layer. This allows the deflection movement of the boundary layer to be transferred to the first electrode and/or the second electrode in a simple manner. For this purpose, the first electrode and the second electrode can be arranged, for example, in planes of the cavity lying on top of each other. The first electrode and/or the second electrode can be directly translationally displaceable by the first and/or second coupling element with the first and/or the second boundary layer. For example, the first electrode or a section of the first electrode can be displaced relative to a fixed second electrode. This causes a uniform change in capacitance between the capacitance measuring sections of the electrodes.

According to one example embodiment of the present invention, the first electrode and/or the second electrode can be tiltable about a tilt axis at least sectionally by the deflection movement of the first boundary layer and/or the second boundary layer. This enables an efficient and space-saving transmission of the deflection movement to the first electrode and/or the second electrode. In particular, a lever mechanism can be realized by the tilt axis and the first coupling element of the first electrode and/or the second coupling element of the second electrode, by means of which a levered larger movement of the electrodes can be generated with a small deflection movement of the boundary layer. The lever mechanism can, for example, be a two-sided lever whose pivot point is formed by the tilt axis, whose force arm is defined by the distance between the coupling element and the tilt axis, and whose load arm can have the capacitance measuring section of the electrode. It is also possible that the tilt axis is formed by a connection point of the electrode to the substrate or fixed body structure of the device. For example, the second electrode can project into the cavity starting from the substrate or fixed body structure of the device, for example starting from a lateral cavity boundary. In this case, the second electrode can form a single-ended lever, around whose pivot point at the cavity boundary the electrode is designed to be tiltable. According to another embodiment, the second electrode can also be designed as a double-ended lever according to the above description.

In other words, an electrode that can be tilted about a tilt axis can be an electrode that can be pivoted about a pivot axis. Tilting and pivoting are understood to mean rotational movements through a limited angle of rotation around an axis of rotation. In particular, tilting and pivoting are understood to mean partial rotations that are less than a full rotation, for example less than 3600 or 2n.

Depending on the design of the movable mounting of the electrodes, combinations of translational, rotational and deformatory mobilities of the electrodes can also be possible. In addition, it is possible, for example, for the first electrode to be designed translationally displaceable and the second electrode to be designed tiltable, or vice versa. In particular, it can also be provided that an electrode is designed to be translationally displaceable in one or more sections of the electrode, tiltable about a tilt axis in one or more other sections and deformable in the intermediate sections in between, so that a combined translational, rotational and deformatory mobility of the electrode is made possible. Deformatory mobility can be understood, for example, as elastic deformability of the electrode.

According to one example embodiment of the present invention, the tilt axis can be formed by a torsion spring. The torsion spring can be connected to the first electrode or integrally formed therewith. The torsion spring can be connected to the second electrode or integrally formed therewith. A torsion spring can, for example, be an elastically twistable bar or strut. The torsion spring can be connected at one end or both ends to the substrate or fixed body structure of the device or to a lateral cavity boundary. Alternatively or additionally, the device can have a rigid frame that extends within the cavity and to which the torsion spring is connected. Due to the elastic twistability of the torsion spring, it can form a tilt axis for the electrode. The torsion spring can extend substantially perpendicular to a load arm and/or force arm, for example substantially perpendicular to a capacitance measuring section of the electrode. A plurality of the electrodes or electrode bars of an electrode designed as an interdigital finger electrode can also be connected to the torsion spring. The device can have a plurality of torsion springs, for example one torsion spring for the first electrode and a second torsion spring for the second electrode, or even a plurality of torsion springs per electrode. The first and second electrodes can be electrically contacted in particular via their torsion spring or their torsion springs and/or the rigid frame. The position of the tilt axis determines the length of the lever arms and therefore the lever effect, i.e., the mechanical magnification of the movement. In addition, the natural resonance frequency of the device can be specifically designed in this way.

According to one example embodiment of the present invention, the first electrode and/or the second electrode can be tiltable about a plurality of tilt axes spaced apart from each other. In this way, for example, two or more different subsections of the electrode can be realized on one electrode, for example subsections that can be tilted in opposite directions to one another. This makes possible, for example, the design of a plurality of shorter lever arms compared to one long lever arm that has a very low natural resonance frequency, which increases the vibrational robustness of the device. The tilt axes can, for example, be formed by torsion springs that are connected to the electrode at a distance from each other. According to one embodiment, the number of tilt axes can be even, for example two, four or six, in order to enable a symmetrical counter-tilting of the electrode. If a plurality of tilt axes are provided, the first electrode can be coupled to the first and/or second boundary layer via a plurality of first coupling elements, and/or the second electrode can be coupled via a plurality of second coupling elements in order to support opposing tilting of electrode sections relative to one another and to enable a stable, uniform tilting of the electrode sections.

According to one example embodiment of the present invention, the first coupling element can be arranged on a section of the first electrode facing a cavity center, and/or the second coupling element can be arranged on a section of the second electrode facing the cavity center. If the electrode is able to move translationally, a uniform displacement of the electrode in the cavity can be achieved thereby. If the electrode can be tilted about a tilt axis, a lever effect of the electrode about the tilt axis in the cavity can be promoted if the coupling element engages a section of the electrode facing the cavity center. For example, a capacitance measuring section of the electrode can be arranged on a section of the first electrode and/or the second electrode facing a lateral cavity boundary, i.e. facing away from the cavity center. The tilting movement makes possible a selectable mechanical translation of a small lift of the boundary layer into a larger lift in the region of the capacitance measuring section via a suitable ratio of the lever arm lengths. In a concentric arrangement, the deflection of the boundary layers can be larger in a central region of the cavity than in a peripheral region of the cavity that is attached to the substrate. As a result of this or, depending on the design, due to a predominantly elongated cavity shape parallel to the boundary layers, there can be less space for deflection of the electrode in the central region than in the peripheral region. It can therefore be favorable and advantageous with regard to an increased signal amplitude to arrange the coupling of the electrode to the boundary layer in a smaller area, for example in a central region of the cavity, and the capacitance measuring section with a high deflection in a larger area, for example in a peripheral region of the cavity. The cavity center can be defined in terms of volume by a geometric center of the cavity volume or in terms of area by a geometric center of a cross-sectional plane of the cavity. For example, the cavity center can have equal distances to opposing lateral cavity boundary surfaces. In a concentric arrangement, the cavity center can lie in the center of the concentric arrangement. While the deflection of the boundary layer can be at its greatest in the cavity center due to its mechanical properties, so that a force arm of the lever can be conveniently placed here, a change in capacitance in this region will only be minimal. In contrast, the outer regions of the concentric arrangement, for example starting from half of the radius of the concentric arrangement, represent a large part, for example, 75% of the capacitive area of the arrangement, so that the capacitive load arm of the lever can advantageously be positioned in such an outer region.

According to some example embodiments of the present invention, the device can have a first boundary layer and a second boundary layer arranged opposite the first boundary layer on the substrate side. The second boundary layer can run parallel to the first boundary layer. The second boundary layer can have a second and/or third electrode which is/are designed as a counter-electrode.

According to one example embodiment of the present invention, the device can have a first boundary layer and a second boundary layer, wherein the cavity is formed between the first boundary layer and the second boundary layer, and wherein the second boundary layer spans a substrate recess introduced into a substrate of the device, wherein the first boundary layer and the second boundary layer are mechanically connected to one another by a connecting element in such a way that they can be deflected together by a fluid pressure acting on the first boundary layer and/or the second boundary layer. In addition, this can prevent collapse as a result of externally acting excess pressure. Due to the simultaneous joint mobility of the interconnected boundary layers, the device can better sense dynamic fluid pressures such as sound waves. The substrate recess can, for example, form a front and/or rear volume. The second boundary layer and the cavity of the device can predominantly or substantially completely span the substrate recess. The substrate recess can encompass the entire extent of the substrate in a direction perpendicular to the main extension direction. Alternatively, the substrate recess can comprise only a part of the extent of the substrate in a direction perpendicular to the main extension direction, wherein the recess can pertain to not only the part facing the device but also the part facing away from the device.

The connecting element with which the first and second boundary layers are connected to each other can act as a driver between the boundary layers and as a stabilizer against the excess pressure acting from the outside. The connecting element can have a length that substantially corresponds to the distance between the boundary layers and a width and height or diameter that extend perpendicular to the length. The connecting element can also have a length that is less than the distance between the boundary layers so that mechanical support only occurs when a predefined external pressure value is reached. The connecting element can have a smaller, in particular several times smaller, width and height or diameter compared to the length, so that, for example, a narrow, rod- or strut-shaped connecting element is formed. The connecting element can extend transversely, for example orthogonally to the boundary layers. The connecting element can cover a connecting surface of the boundary layer at the connection point, which can be, for example, less than 10%, in particular less than 5% or 2% of the total boundary layer surface. The connection of the boundary layers can therefore be an essentially punctiform connection. The device can also have a plurality of connecting elements spaced apart from each other that connect the first boundary layer to the second boundary layer. The connecting elements can in particular be formed from an insulating material so that the two boundary layers can be electrically insulated from each other.

According to one example embodiment of the present invention, the connecting element can be mechanically decoupled from the electrodes so that a transmission of a deflection movement of the boundary layers to the first and/or second electrode only takes place at specific points via the coupling element. The first electrode and/or the second electrode can, for example, have a recess or a gap in the region of the connecting element so that the connecting element can project through or past the first and/or second electrode. According to another embodiment, the connecting element can also be designed as a coupling element, for example connected to the boundary layers and to the first and/or second electrode so that the electrode can be deflected together with the boundary layers via a combined coupling-connecting element.

The first electrode can be coupled to the first boundary layer via a first coupling element, and/or the second electrode can be coupled thereto via a second coupling element. Alternatively or additionally, it is possible for the first electrode to be coupled to the second boundary layer via a first coupling element, and/or for the second electrode to be coupled thereto via a second coupling element.

According to one example embodiment of the present invention, the device can have a pressure equalization channel running through the first boundary layer and the second boundary layer and opening into the substrate recess. This enables a defined quasi-static pressure equalization between the substrate recess and the environment. The measuring signal is thereby independent of pressure fluctuations in the environment. The pressure equalization channel can run substantially transversely, in particular orthogonally to the boundary layers. The first boundary layer can have a first pressure equalization opening, and the second boundary layer can have a second pressure equalization opening between which the pressure equalization channel runs. The pressure equalization openings can, for example, be arranged substantially in the middle in the boundary layers. The pressure equalization channel can have a smaller cross-sectional area perpendicular to its longitudinal extension between the boundary layers than a first or second coupling element, or than a connecting element perpendicular to its longitudinal extension between the boundary layers. The pressure equalization channel can run through a coupling element or be laterally limited by coupling elements. The pressure equalization channel can therefore be hermetically sealed against the cavity.

The first electrode and/or the second electrode and/or their capacitance measuring sections can in principle be designed, for example, as a planar plate electrode or planar plate electrodes. According to one embodiment, the first electrode and/or the second electrode can have a plurality of electrode bars extending substantially parallel to one another. The first electrode and/or the second electrode can therefore also be designed as a bar or interdigital finger electrode. Such an electrode shape is associated with a high capacitive surface density. In addition, electrode bars can be more flexible than planar electrode surfaces due to their shape. The first electrode and/or the second electrode can have, for example, a rectangular planar electrode base surface from which the electrode bars project. By a defined arrangement of planar electrode base surfaces and electrode bars relative to each other, less and more mobile or less and more deformable regions of the electrode in the cavity can be specified. The electrode bars can also project from a first and/or second boundary layer of the device, in particular if the second electrode or a third electrode is arranged in the boundary layer or is formed thereby. The first electrode and/or the second electrode can have a plurality of electrode base surfaces between which the electrode bars extend and to which the electrode bars are connected. In this embodiment, an electrode base surface can advantageously form a capacitance measuring section since it can be displaced approximately translationally during the tilting movement of the electrode bars and can therefore provide a defined and precise measuring signal. The first and/or second boundary layer can be coupled via a coupling element to an electrode base surface or to an electrode bar of the first or second electrode, depending on the embodiment. Several or all electrode bars of the first and/or the second electrode can also be coupled to the first and/or the second boundary layer by coupling elements. In a gap between two electrode bars, a connecting element can extend between the first and the second boundary layer. The electrode bars of an electrode can, for example, extend substantially parallel to the first boundary layer when the latter is not deflected. According to one embodiment, the electrode bars of, for example, the second electrode can also extend transversely, for example orthogonally to the first boundary layer or transversely, for example orthogonally to the non-deflected first electrode, whereby compact electrode arrangements can be made possible. Accordingly, depending on the embodiment, the electrode bars can run horizontally or vertically in the cavity.

According to one example embodiment of the present invention, the electrode bars of the first electrode can dip at least sectionally into gaps between the electrode bars of the second electrode. Alternatively or additionally, the electrode bars of the second electrode can dip at least sectionally into the gaps between the electrode bars of the first electrode. This creates a very compact electrode arrangement with a high capacitive surface density. For example, the capacitance measuring sections of the first and second electrodes can extend parallel to one another, at least in a non-deflected state of the electrodes, such that the electrode bars of one electrode at least partially project into the gaps between the electrode bars of the other electrode. If the position of at least one of the electrodes changes, for example if at least one electrode is tilted, the degree to which the electrode bars dip into the gaps can be changed by the relative movement of the electrodes to one another, which can cause a significant change in capacitance and an associated pronounced measurement signal.

According to one example embodiment of the present invention, the device can have a plurality of first electrodes and/or one or more second electrodes that are arranged symmetrically to a cavity center in the cavity. For example, the first electrodes and/or the second electrode or second electrodes can be mirror-symmetrical or point-symmetrical to a cavity center. The first electrodes and/or the second electrode or second electrodes can, for example, be arranged concentrically to the cavity center. The first electrodes and/or the second electrode or second electrodes can be arranged periodically in the cavity. An area- and installation-space-optimized arrangement of the electrodes with a high structural density can be achieved by the aforementioned arrangement options. For example, the cavity can have a rectangular cross-section in which the first electrodes and/or the second electrode or the second electrodes are aligned symmetrically, concentrically and/or periodically in relation to a cavity center of the cavity cross-section. The cavity center can be defined in terms of volume by a geometric center of the cavity volume or in terms of area by a geometric center of a cross-sectional plane of the cavity. The first electrodes and/or the second electrodes can, for example, form common electrode groups, wherein, for example, four electrode groups can be arranged offset at an angle of 90° to one another around a central axis running through the cavity center perpendicular to the boundary layer. The first electrodes and/or the second electrode or the second electrodes can have a symmetrical arrangement with respect to an axis of symmetry running through the cavity, or with respect to a point of symmetry located in the cavity center. In the case of a symmetrical, concentric and/or periodic arrangement of the electrodes, the device can have a rigid, for example cruciform frame which runs through the cavity and to which components such as a torsion spring of an electrode can be connected.

According to one example embodiment of the present invention, the device can have a rigid frame dividing the cavity into a plurality of segments, wherein a first electrode is arranged in each segment and is tiltable at least sectionally about a tilt axis defined by a torsion spring, wherein the torsion spring is connected to the rigid frame. In this way an area- and installation-space-optimized arrangement of the electrodes with a high structural density can be achieved. The rigid frame can, for example, run through the cavity in the shape of a cross or a star. The rigid frame allows the cavity to be divided into an even or odd number of segments. According to one exemplary embodiment, the cavity can be divided by the rigid frame into, for example, four segments. The first electrodes can be aligned symmetrically, for example concentrically in relation to a cavity center and/or arranged periodically in the segments. A capacitance measuring section of the first electrode in a segment can face the cavity boundary. A first coupling element for coupling the first electrode to the first and/or second boundary layer can be arranged facing a cavity center. The first electrodes in the segments can each be suspended from the rigid frame by a spring, such as a torsion spring. Electrode recesses can be introduced sectionally into the first electrode in order to reduce parasitic capacitances. In addition, an improved mobility of the electrode regions of the first electrode between the electrode recesses is achieved, which can, for example, form electrode bars of the first electrode.

According to one design of the above-described embodiment of the present invention, the second electrode and/or optionally a third electrode can be arranged in or on the first boundary layer and/or in or on the second boundary layer, or be formed by the first boundary layer and/or by the second boundary layer, and segmented by one or more segment insulations such that an electrode segment of the second and/or the third electrode is assigned to a segment with a first electrode. This enables particularly precise, segment-focused, low-parasitic detection of capacitive measurement signals, and advantageously also of differential-capacitive measurement signals when there are three electrodes. In other words, a capacitance measuring section of the second electrode and of the third electrode can be formed between two segment insulations of the second electrode, which is configured to form one or two measuring capacitors with a capacitance measuring section of a first electrode of an associated segment.

According to one example embodiment of the present invention, the cavity can have a substantially circular or alternatively a substantially rectangular cross-section. In this way an area- and installation-space-optimized arrangement of the electrodes with a high structural density can be achieved.

The structural components of the device described within the context of this application, for example the first electrode, the second electrode, the substrate, the boundary layer, the coupling element, the connecting element, the rigid frame, the torsion spring and other mentioned elements can be made, for example, from silicon, metals such as aluminum, titanium nitride or tungsten, and/or from silicon compounds or other semiconductor materials. The device can be manufactured by depositing, structuring and etching layers of material on a substrate.

The microelectromechanical device can be configured to sense fluid pressures or fluid mass flows. For example, the microelectromechanical device can be configured for static or quasi-static absolute pressure measurement of an ambient pressure. In this case, the device can advantageously have a deflectable boundary layer. The microelectromechanical device can also be designed for static, quasi-static or dynamic measurement of relative pressure changes that are generated, for example, by sound vibrations. In this case, the device can advantageously have two deflectable boundary layers mechanically coupled to each other and a substrate recess.

The present invention also relates to a microelectromechanical pressure sensor which has a microelectromechanical device according to one of the above-described features and a signal processing unit for applying and processing signals from the microelectromechanical device. This makes it possible to provide a very compact and powerful pressure sensor with very sensitive, particle-insensitive pressure measurement, a very good signal-to-noise ratio and reduced fluidic squeeze-film damping effects. The pressure sensor can be designed in particular as an absolute pressure sensor or relative pressure sensor for measuring static or quasi-static fluid pressures, for example an ambient pressure of the pressure sensor. The pressure sensor can in particular have a boundary layer, according to one embodiment even exactly one, which can be deflected relative to a substrate of the device, and which is coupled to the first electrode by a first coupling element in order to transmit a deflection movement to a first electrode movably mounted in a cavity between a substrate and the boundary layer. The microelectromechanical pressure sensor can, for example, be implemented as a system-on-chip (SoC).

The present invention also relates to a microelectromechanical microphone for capacitive sound pressure measurement, which has a microelectromechanical device according to one of the features described above and a signal processing unit for applying and processing signals from the microelectromechanical device. This makes it possible to provide a very compact and powerful microphone with very sensitive, particle-insensitive sound pressure measurement, a very good signal-to-noise ratio, and reduced fluidic squeeze-film damping effects. The microphone can be a capacitive microphone, i.e. an electroacoustic transducer that converts sound into a corresponding electrical signal by detecting capacitance changes caused by changes in the distance between the movable first electrode and the second electrode. The microphone can in particular have a device of the above-described type which has a first boundary layer, a second boundary layer and a substrate recess adjacent to the second boundary layer, wherein the first boundary layer and the second boundary layer are mechanically connected to one another by a connecting element in such a way that they can be deflected together by a fluid pressure acting on the first or second boundary layer. Due to the simultaneous joint mobility of the interconnected boundary layers, the device can sense sound waves better. The substrate recess can, for example, form a front or rear volume. The microelectromechanical microphone can, for example, be implemented as a system-on-chip (SoC).

The present invention also relates to a microelectromechanical combination sensor element which comprises a microphone for capacitive sound pressure measurement, and/or an absolute pressure sensor, and/or a relative pressure sensor which has a microelectromechanical device according to one of the above-described features and a signal processing unit for applying and processing signals from the microelectromechanical device. This can be realized, for example, in that a first device with a substrate recess as a microphone is placed on the same chip next to a second device without a substrate recess as an absolute pressure sensor. This makes it possible to provide a very compact and powerful combination sensor element.

In general, in the context of this application, the words “a/an” are to be understood as indefinite articles with the literal meaning of “at least one”.

The present invention allows for various embodiments and is explained in more detail below using an exemplary embodiment with the figures.

### BRIEF DESCRIPTION OF THE DRAWINGS

FIGS. 1A and 1B show a microelectromechanical device according to a first embodiment in a cross-sectional plan view and a lateral cross-sectional view, according to the present invention.

FIGS. 2A-2C show a microelectromechanical device according to a second embodiment in a cross-sectional plan view and two lateral cross-sectional views, according to the present invention.

FIGS. 3A and 3B show a microelectromechanical device according to a third embodiment in a cross-sectional plan view and a lateral cross-sectional view, according to the present invention.

FIGS. 4A and 4B show a microelectromechanical device according to a fourth embodiment in a cross-sectional plan view and a lateral cross-sectional view, according to the present invention.

FIGS. 5A-5C show two variants of a microelectromechanical device according to a fifth embodiment in a cross-sectional view, a lateral cross-sectional view and another cross-sectional view, according to the present invention.

FIGS. 6A and 6B show a microelectromechanical device according to a sixth embodiment in a cross-sectional plan view and a lateral cross-sectional view, according to the present invention.

FIGS. 7A and 7B show a microelectromechanical device according to a seventh embodiment in a cross-sectional plan view and a lateral cross-sectional view, according to the present invention.

FIGS. 8A and 8C show a microelectromechanical device according to an eighth embodiment in two cross-sectional views and a lateral cross-sectional view, according to the present invention.

FIG. 9 shows a schematic diagram of a microelectromechanical pressure sensor with a microelectromechanical device, according to an example embodiment of the present invention.

### DETAILED DESCRIPTION OF EXAMPLE EMBODIMENTS

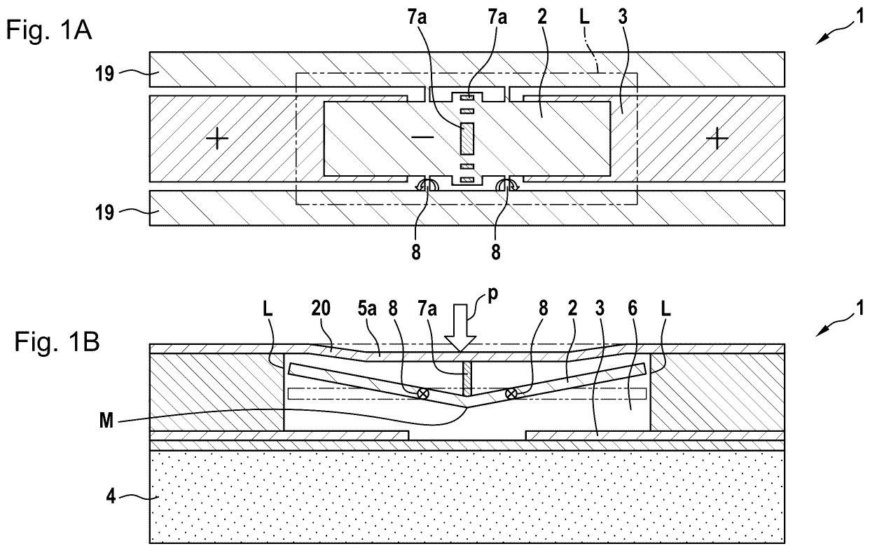

FIGS. 1A and 1B show a microelectromechanical device 1 according to a first embodiment. FIG. 1A shows a cross-sectional view, FIG. 1B a lateral cross-sectional view of the device 1. The microelectromechanical device 1 is designed for the capacitive measurement of fluid pressures or fluid mass flows. For this purpose, the device 1 has a first electrode 2 and a second electrode 3 which can be planar surface electrodes as shown in the figures. The device 1 has a substrate 4 and a first boundary layer 5a extending at a distance from the substrate 4. The first boundary layer 5a is designed as an elastically deflectable membrane and can extend in a non-deflected state substantially parallel to a substrate surface or substrate plane of the substrate 4. In FIG. 1B, the first boundary layer 5a is shown in a deflected state, wherein a rest position of the first boundary layer 5a in a non-deflected state is indicated by a dot-dashed line. The deflection of the first boundary layer 5a can be caused, as shown, by an external fluid pressure p on the first boundary layer 5a. As described above, a third electrode 20 can be arranged in or on the first boundary layer 5a or formed thereby.

In the device 1, a cavity 6 is formed which is delimited by the substrate 4, the first boundary layer 5a and a lateral cavity boundary L (dash-dotted line in FIG. 1A). The cavity 6 can be sealed fluid-tight. Advantageously, a gas volume that has a gas pressure below ambient air pressure can be enclosed in the cavity 6. The cavity 6 has a geometrically defined cavity center M at the center of the cavity 6. The first electrode 2 and the second electrode 3 are arranged in the cavity 6. While the second electrode 3 according to the embodiment shown is designed as a fixed electrode 3, the first electrode 2 is movably mounted. In this regard, it can be seen from FIG. 1B that the first electrode 2 can be tilted about two tilt axes 8 by the deflection movement of the first boundary layer 5a, whereby a space-saving transmission of the deflection movement to the first electrode 2 is possible. The tilt axes 8 are formed by elastically twistable torsion springs which are connected at one end to the first electrode 2 and at the other end to the cavity boundary L of the device 1. By means of two tilt axes 8 spaced apart from one another, subsections of the first electrode 2 can be tilted in opposite directions to one another, as shown. In FIG. 1B, the first electrode 2 is shown in a deflected state, wherein a rest position of the electrode 2 in a non-deflected state is indicated by a dot-dashed line. The first electrode 2 is mechanically coupled to the first boundary layer 5a by a plurality of first coupling elements 7a. As a result, a deflection movement of the first boundary layer 5a can be transmitted to the first electrode 2 so that the first electrode 2 executes a relative movement with respect to the second electrode 3 due to the tilting and causes a measurable change in capacitance with respect to an initial capacitance. The capacitance change can be detected as an electrical signal which depends on the deflection movement of the first boundary layer 5a. At the same time, a further change in capacitance between the first electrode 2 and third electrode 20 can be detected as a signal, and a difference signal can therefore be formed as a measurement variable for the pressure.

The device 1 has a very compact measuring mechanism. By coupling the deflectable first boundary layer 5a to the first electrode 2, a direct transmission of the deflection movement via cavity structures of the device 1 is effected, and the measuring mechanism of the device 1 is thereby concentrated in the smallest possible space. With the measuring mechanism integrated into the cavity 6 of the device 1, a sensitive, particle-insensitive capacitive pressure measurement with a very good signal-to-noise ratio can be achieved.

According to the schematically illustrated embodiment, the first coupling elements 7a are rod-shaped and have a smaller width and height than length, wherein the length can be defined substantially by the distance between the coupling point of the first coupling element 7a to the first electrode 2 and to the first boundary layer 5a. This enables an essentially punctiform coupling of the first electrode 2 to the first boundary layer 5a. The first coupling elements 7a extend substantially perpendicular to the first electrode 2 and the boundary layer 5.

The device 1 shown in FIGS. 1A and 1B can be used, for example, as a capacitive measuring device of an absolute pressure sensor. In this case, the fluid pressure p can, for example, be a static or quasi-static ambient fluid pressure, and the device 1 can be configured to measure absolute pressure values. In the following exemplary embodiments, the fluid pressure p can, for example, also be a dynamic fluid pressure, and the device 1 can be configured to measure relative pressure changes so that the device 1 can also be used as a capacitive measuring device of a microphone.

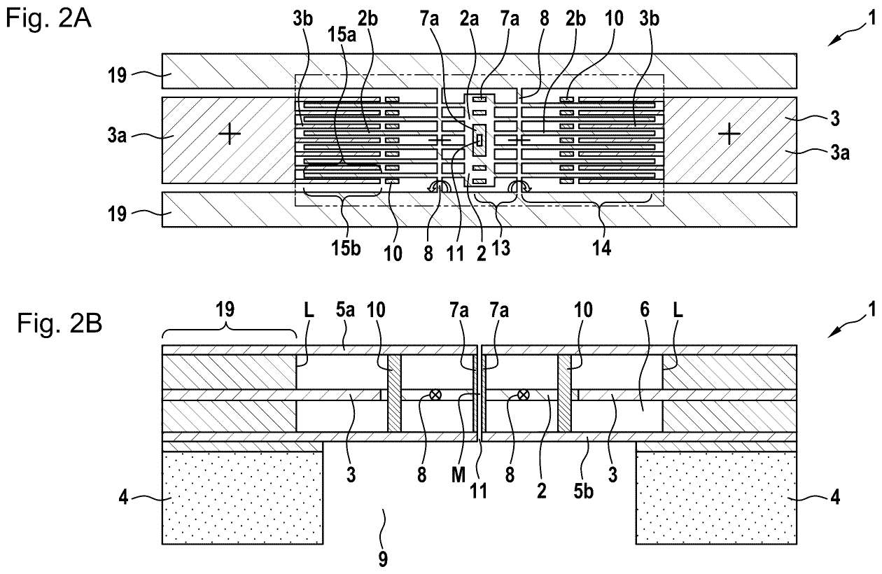

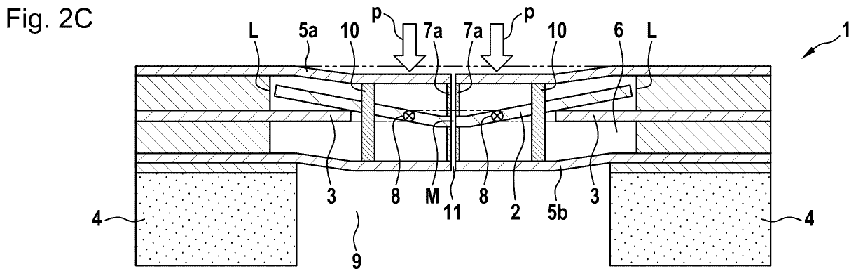

FIGS. 2A, 2B and 2C show a microelectromechanical device 1 according to a second embodiment. FIG. 2A shows a cross-sectional plan view, FIG. 2B shows a lateral cross-sectional view of the device 1 in a non-deflected state of a first boundary layer 5a, and FIG. 2C shows a cross-sectional view of the device 1 in a state of the first boundary layer 5a deflected by a fluid pressure p. The microelectromechanical device 1 is designed for the capacitive measurement of, in particular, dynamic fluid pressures or fluid mass flows, for example for the detection of sound vibrations. For this purpose, the device 1 has a first electrode 2 and a second electrode 3 which can be finger or bar electrodes as shown in FIG. 2A. Here, the first electrode 2 has a plurality of electrode bars 2b extending parallel to one another which project from a planar electrode base surface 2a. In addition, the second electrode 3 has a plurality of electrode bars 3b extending parallel to one another which project from a planar electrode base surface 3a. The electrode bars 2b of the first electrode 2 and the electrode bars 3b of the second electrode 3 extend substantially parallel to the boundary layers 5a, 5b.

The device 1 has a first boundary layer 5a and a second boundary layer 5b arranged on the substrate side and opposite the first boundary layer 5a. According to the shown exemplary embodiment, the boundary layers 5a, 5b are designed as elastically deflectable membranes. The first boundary layer 5a and the second boundary layer 5b extend substantially parallel to one another, in particular in a non-deflected state. A substrate recess 9 is introduced into the substrate 4 adjacent to the second boundary layer 5b. The second boundary layer 5b spans the substrate recess 9. Between the first boundary layer 5a and the second boundary layer 5b, a cavity 6 is formed in which the first electrode 2 is movably mounted and the second electrode 3 is fixedly arranged. The cavity 6 is additionally delimited between the boundary layers 5a, 5b by a fixed body structure 19 and lateral cavity boundaries L of the fixed body structure 19.

The first boundary layer 5a and the second boundary layer 5b are connected to one another by connecting elements 10 and can therefore be simultaneously deflected together by a fluid pressure p acting on the first or second boundary layer 5a, 5b. FIG. 2B shows the non-deflected state, i.e. a rest position of the boundary layers 5a, 5b. In FIG. 2C, the boundary layers 5a, 5b are shown in a deflected state, wherein the respective rest position of the boundary layers 5a, 5b is indicated by a dot-dashed line. The deflection of the first boundary layer 5a can be caused, as shown, by an external fluid pressure p on the first boundary layer 5a. According to the schematically illustrated embodiment, the connecting elements 10 are rod-shaped and have a smaller width and height than length, wherein the length can be defined substantially by the distance between the boundary layers 5a, 5b. This enables an essentially punctiform connection of the boundary layers 5a, 5b to one another. The connecting elements 10 extend substantially perpendicular to the boundary layers 5a, 5b. According to the embodiment shown, the connecting elements 10 are mechanically decoupled from the electrodes 2, 3 and in this case only connect the boundary layers 5a, 5b to one another. For this purpose, the connecting elements 10 are arranged, for example as shown, in gaps between electrode bars 2a of the first electrode 2 and project between the electrode bars 2a.

The cavity 6 can be sealed fluid-tight. Advantageously, a gas volume that has a gas pressure below ambient air pressure can be enclosed in the cavity 6. The cavity 6 has a geometrically defined cavity center M in the center of the cavity 6. The first electrode 2 and the second electrode 3 are arranged in the cavity 6. The second electrode 3 is integrated into the lateral cavity boundary L with an electrode base surface 3a, starting from which the electrode bars 3b of the second electrode 3 project into the cavity 6 in the direction of the cavity center M. The second electrode 3 extends substantially parallel to the substrate plane of the substrate 4, wherein the substrate plane can be defined by the largest planar extension of the substrate 4. While the second electrode 3 according to the shown embodiment is designed as a fixed electrode 3, the first electrode 2 is movably mounted. In this regard, it can be seen from FIG. 2C that the first electrode 2 can be tilted about two tilt axes 8 by the deflection movement of the boundary layers 5a, 5b, whereby a space-saving transmission of the deflection movement to the first electrode 2 is possible. The tilt axes 8 are formed by elastically twistable torsion springs which are connected on the one hand to the electrode bars 2b of the first electrode 2, and on the other hand to the lateral cavity boundary L of the device 1. By means of two tilt axes 8 spaced apart from one another, subsections of the first electrode 2 can be tilted in opposite directions to one another, as shown. The first electrode 3 is mechanically coupled to the first boundary layer 5a and to the second boundary layer 5b by a plurality of first coupling elements 7a. As a result, a deflection movement of the boundary layers 5a, 5b can be transmitted to the first electrode 2 so that the first electrode 2 can execute a relative movement with respect to the second electrode 3 due to the tilting and can cause a measurable change in capacitance with respect to an initial capacitance. The capacitance change can be detected as an electrical signal which depends on the deflection movement of the boundary layers 5a, 5b.

By means of a tilt axis 8 and a first coupling element 7a of the first electrode 1, a lever mechanism can be realized by means of which a larger tilting movement of the first electrode 1 can be generated with a small deflection movement of the boundary layers 5a, 5b. As indicated in FIG. 2A, the lever mechanism can be a double-ended lever whose pivot point is formed by the tilt axis 8. The force arm 13 of the lever is defined by the distance between the coupling element 7a and the tilt axis 8, while the load arm 14 is formed by a section of the first electrode 2 opposite the force arm 13. As shown, the force arm 13 can be shorter than the load arm 14 so that, with a small deflection movement of the force arm 13, a high signal amplitude in the load arm 14 is made possible.

As shown in FIG. 2A, the first electrode 2 can have first capacitance measuring sections 15a which are substantially opposite the second capacitance measuring sections 15b of the second electrode 3 so that the electrical capacitance between the capacitance measuring sections 15a, 15b can be detected. In this case, the electrode bars 2b of the first electrode 2 sectionally dip in the gaps between the electrode bars 3b of the second electrode 3 and vice versa, wherein the degree of dipping is changed during a tilting movement of the first electrode 2 as shown in FIGS. 2B and 2C since the electrode bars 2b of the first electrode 2 are partially tilted out of the plane of the electrode bars 3b of the second electrode 3. According to the illustration, the coupling elements 7a of the first electrode 2 are arranged on a section of the first electrode 2 which faces away from the capacitance measuring sections 15a of the first electrode 2. A capacitance measuring section 15a of the first electrode 2 can be assigned in this case to the load arm 14 of the lever explained above with reference to FIG. 2A. The first coupling elements 7a are arranged on sections of the first electrode 2 facing the cavity center M, while the capacitance measuring sections 15a of the first electrode 2 are arranged on sections of the first electrode 2 facing the lateral cavity boundary L.

The first electrode 2 forms, with the second electrode 3, a first measuring capacitor from which a 2f signal can be tapped. By arranging a third electrode 20 or third electrodes 20 (not shown in detail) as a flat, additional counter-electrode or counter-electrodes in or on one or both of the boundary layers 5a, 5b, optionally at least one additional measuring capacitor can be formed with the first electrode 2 at which a 1f signal can be tapped. The 2f measurement signal of the first measuring capacitor and the 1f signal of the second measuring capacitor can advantageously be acquired simultaneously and reckoned up to form a final measurement signal. Furthermore, it is not shown in more detail that the first electrode 2 can have at least one insulating stop in order to prevent the electrode 2 from welding to a surrounding structure in the event of an overload. For example, such stops can be arranged on the tiltable electrode bars of the first electrode 2 or on the boundary layers 5a, 5b.

The device 1 has a very compact measuring mechanism. By coupling the deflectable boundary layers 5a, 5b to the first electrode 2, a direct transmission of the deflection movement via cavity structures of the device 1 is effected, and the measuring mechanism of the device 1 is thereby concentrated in the smallest possible space. With the measuring mechanism integrated into the cavity 6 of the device 1, a sensitive, particle-insensitive capacitive pressure measurement with a very good signal-to-noise ratio can be achieved.

According to the schematically illustrated embodiment, the first coupling elements 7a are rod-shaped and have a smaller width and height than length, wherein the length can be defined substantially by the distance between the first boundary layer 5a and the second boundary layer 5b. This enables an essentially punctiform coupling of the first electrode 2 to the boundary layers 5a, 5b. The first coupling elements 7a extend substantially perpendicular to the first electrode 2 and the boundary layers 5a, 5b. In this embodiment, the coupling elements 7a are advantageously arranged as shown on the planar electrode base surface 2a of the first electrode 2. This allows a uniform and stable deflection of the electrode 2 on the electrode base surface 2a by the coupling elements 7a while the electrode bars 2b can be easily tilted about the tilt axis 8.

According to the illustrations in FIGS. 2A-2C, a pressure equalization channel 11 runs between the first boundary layer 5a and the second boundary layer 5b and opens into the substrate recess 9. This enables a defined quasi-static pressure equalization between the substrate recess 9 and the environment. In the embodiment shown, the pressure equalization channel 11 runs substantially through the cavity center M and through a first coupling element 7a.

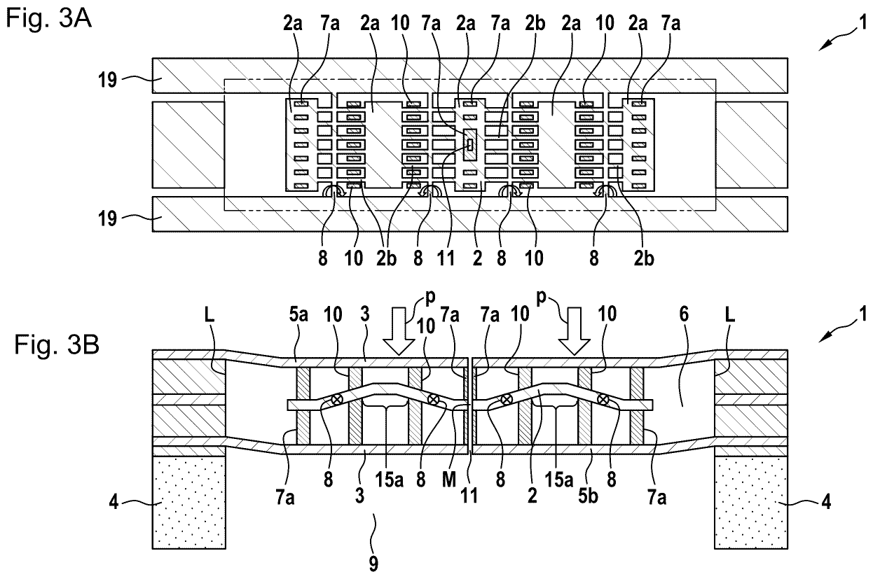

FIGS. 3A and 3B show a microelectromechanical device 1 according to a third embodiment. FIG. 3A shows a cross-sectional plan view and FIG. 3B a lateral cross-sectional view of the device 1 in a deflected state of the boundary layers 5a, 5b. In its basic structure and functional principle, the device 1 shown is comparable to the device 1 according to the second embodiment. In the device 1 according to the third embodiment, the first electrode 2 has additional tilt axes 8, here a total of four tilt axes 8. As a result, the first electrode 2 has a plurality of subsections which can be tilted in opposite directions to one another about the tilt axes 8 and which form a plurality of shorter lever arms with a higher natural resonance frequency. The tilt axes 8 are arranged symmetrically in relation to a cavity center M and substantially perpendicular to the electrode bars 2b. The tilt axes 8 are designed as torsion springs and attached to the cavity boundaries L of the device 1. In this embodiment, the first electrode 2 has a plurality of electrode base surfaces 2a, between which the electrode bars 2b extend. This can increase the stability of the electrode 2 and achieve a defined deflection of the electrode bars 2b. First coupling elements 7a for coupling the first electrode 2 to the boundary layers 5a, 5b are provided on the outer electrode base surfaces 2a and on the middle electrode base surface 2a of the first electrode 2, while the electrode base surfaces 2a arranged between the outer and middle electrode base surfaces 2a do not have any coupling elements 7a. These electrode base surfaces 2a can advantageously form capacitance measuring sections 15a since they can be moved approximately translationally towards or away from the second electrode 3 during the tilting movement of the electrode bars 2b. In this way a very precise measurement signal can be generated. In the third embodiment, the second electrode 3 is formed by the boundary layers 5a and/or 5b, as shown in FIG. 3B.

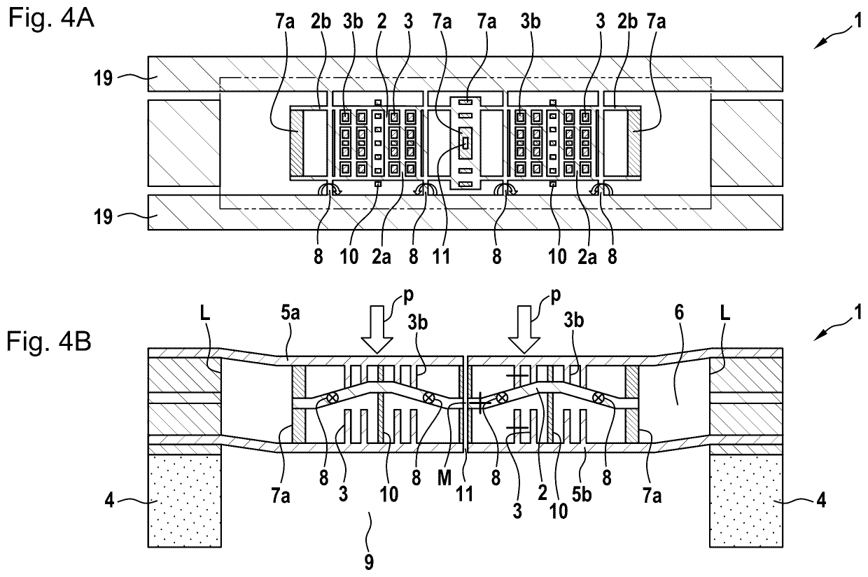

FIGS. 4A and 4B show a microelectromechanical device 1 according to a fourth embodiment. FIG. 4A shows a cross-sectional plan view and FIG. 4B a lateral cross-sectional view of the device 1 in a deflected state of the boundary layers 5a, 5b. In its basic structure and functional principle, the shown device 1 is comparable to the device 1 according to the third embodiment; for example, the device 1 has several, here four, tilt axes 8. However, in the device 1 according to the fourth embodiment, electrode base surfaces 2a are also tilted about the tilt axes 8. In addition, electrode bars 3b of the second electrode 3 project vertically from the first and second boundary layers 5a, 5b into the cavity 6 towards the first electrode 2. The vertical electrode bars 3b extend substantially perpendicular to the boundary layers 5a, 5b. This makes it possible to create a compact electrode arrangement with a high capacitive surface density. Connecting elements 10 for connecting the boundary layers 5a, 5b to one another extend between the vertically positioned electrode bars 3b of the second electrode 3 and between the electrode base surfaces 2a of the first electrode 2. In the region of the cavity center M and at the outer end sections of the first electrode 2 facing the lateral cavity boundary L, first coupling elements 7a are arranged which couple the first electrode 2 to the boundary layers 5a, 5b. As shown in FIG. 4A, the first coupling elements 7a at the end sections of the first electrode 2 in this embodiment are not designed as rod-shaped coupling elements 7a, but as a bridge structure extending over the entire width of the electrode 2. This allows a favorable force transmission to the electrode 2. As is clear from FIG. 4A, the device 1 according to the fourth embodiment has a high structure density due to its compact electrode arrangement so that an efficient use of the area of the micromechanical component is ensured.

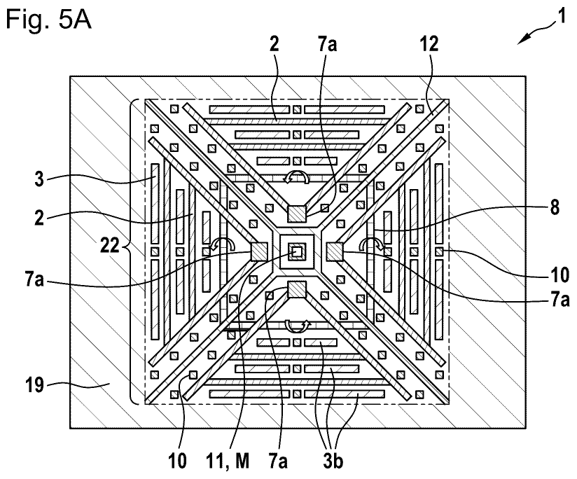

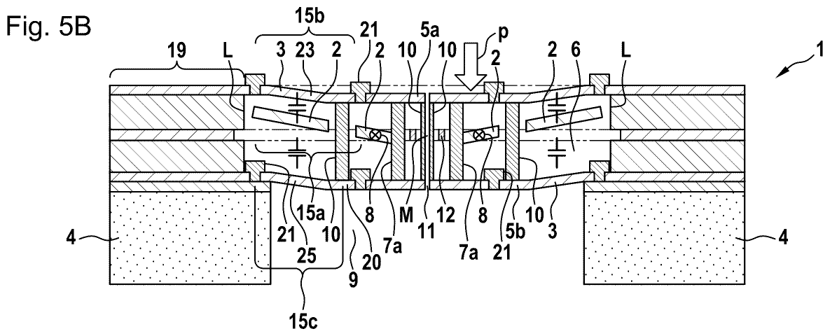

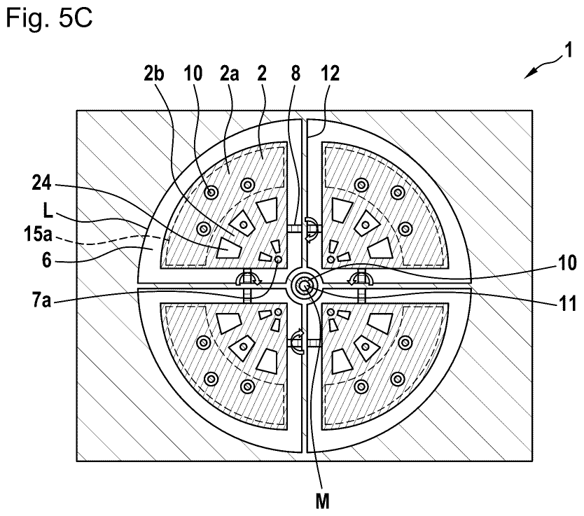

FIGS. 5A to 5C show a device 1 according to a fifth embodiment, wherein FIG. 5A shows a first variant with a rectangular cavity, and FIGS. 5B and 5C show a second variant of the fifth embodiment with a circular cavity. In the fifth embodiment, the device 1 has a rigid frame 12 dividing the cavity 6 into segments 22, wherein a first electrode 2 is arranged in each segment 22 and is tiltable at least sectionally about a tilt axis 8 defined by a torsion spring, wherein the torsion spring is connected to the rigid frame 12. The rigid frame 12 in turn is anchored to the lateral cavity boundary L on the fixed body structure 19.

FIG. 5A shows, for example, in a cross-sectional view, a device 1 according to the fifth embodiment with a rectangular cross-section of the cavity 6 in which the cavity structures, in particular the first electrodes 2 and the second electrodes 3 of the device 1, are aligned symmetrically and concentrically in relation to the cavity center M. The first electrodes 2 and the second electrodes 3 form four electrode groups, each of which is rotated at an angle of 90° to each other around the cavity center M. A rigid frame 12 is arranged in the cavity 6 and fastened to the cavity boundary L of the device 1. The rigid frame 12, shown here in a cross shape, divides the cavity into four segments (22) in which the electrode groups are arranged, wherein the rigid frame 12 has a subframe around the cavity center M and the pressure equalization channel 11 which is mechanically decoupled from the rigid frame 12. A first part of the first electrode 2 in each section extends parallel to the rigid frame 12 with two electrode bars 2b running at an angle towards each other, which in turn are connected by additional electrode bars 2b running as cross-braces between the electrode bars 2b. Between the cross-braces, electrode bars 3b of the second electrode 3 extend as vertically positioned electrode bars 3b below and/or above the first electrode 2, analogous to the fourth embodiment. The tilt axes 8 designed as torsion springs run parallel to the cavity boundary of the cavity 6 and form a rectangle over all four segments 22, in the corners of which the torsion springs are connected to the rigid frame 12. A first coupling element 7a is arranged at each angle of the electrode bars 2b of the first electrode 2 that run at an angle towards one another, and connects the first electrode 2 to the boundary layers 5a, 5b. Connecting elements 10 which connect the boundary layers 5a, 5b to one another are arranged between the rigid frame 12 and the electrode bars 2b of the first electrode 2 that run at an angle towards one another, as well as in the region of the electrode bars 3b of the second electrode 3. To illustrate the mechanism of the fifth embodiment, one can conceptualize a fluid pressure p acting on the coupling elements 7a into the plane of the paper. The electrode bars 2b running at an angle towards the coupling element 7a are pressed down into the plane of the paper up to the tilt axis 8, but at the same time, due to their tilt axis 8, they pivot out of the plane of the paper in their region between the vertical electrode bars 3b of the second electrode 3 so that a change in capacitance is generated between the finger electrodes 2b, 3b. The device 1 according to the fifth embodiment makes possible a very favorable use of area.

FIGS. 5B and 5C show a lateral cross-sectional view and a cross-sectional plan view of a device 1 with a circular cross-section of the cavity 6. The device 1 has a rigid, in this case cruciform frame 12 which in this case divides the cavity 6 into four segments 22. A subframe of the rigid frame 12 is formed around a mechanically decoupled pressure equalization channel 11. A first electrode 2 is arranged in each segment 22. The first electrode 2 has electrode recesses 24 to reduce parasitic capacitances. The electrode regions formed between the electrode recesses 24 form electrode bars 2b of the first electrode 2. The first electrode 2 in each segment 22 can be tilted at least sectionally about a tilt axis 8 defined by a torsion spring, wherein the torsion spring is connected to the rigid frame 12. The first electrodes 2 are symmetrical, in this case concentrically aligned to a cavity center M and arranged periodically in the segments 22. The capacitor sections 15a of the first electrodes 2 face a cavity boundary L. The first coupling elements 7a of the first electrodes 2 face the cavity center M. As can be seen in FIG. 5B, the second electrode 3 is formed in this case in the first boundary layer 5a, and a third electrode 20 is formed in the second boundary layer 5b and segmented by a plurality of segment insulations 21, wherein an electrode segment 23 of the second electrode 3 and an electrode segment 25 of the third electrode 20 are assigned to a segment 22 with a first electrode 22. In other words, between two segment insulations 21 of the second electrode 3 and third electrode 20, a capacitance measuring section 15b of the second electrode 3 is formed as well as a capacitance measuring section 15c of the third electrode 20 which is configured to form two measuring capacitors with a capacitance measuring section 15a of a first electrode 2 of an associated segment 22. The boundary layers 5a, 5b are coupled to one another by connecting elements 10 and can be deflected together. By means of first coupling elements 7a, the first electrodes 2 can be deflected together with the boundary layers 5a, 5b and tilted about the tilt axis 8.

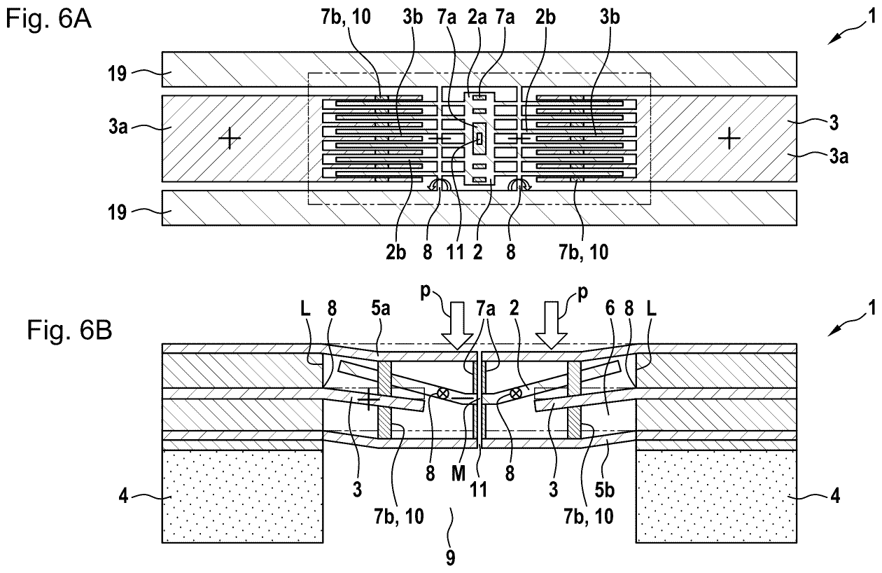

FIGS. 6A and 6B show a microelectromechanical device 1 according to a sixth embodiment. FIG. 6A shows a cross-sectional plan view and FIG. 6B a lateral cross-sectional view of the device 1 in a deflected state of the boundary layers 5a, 5b. In its basic structure and functional principle, the shown device 1 is comparable to the device 1 according to the second embodiment. In the device 1 according to the sixth embodiment, the second electrode 3 is also movably mounted and coupled to the boundary layers 5a, 5b by a second coupling element 7b. As indicated in FIG. 6B by the illustrated arrow, the first electrode 2 and the second electrode 3 can therefore be tilted in opposite directions to each other in order to make possible a larger relative movement of the first and second electrodes 2, 3 to each other and thereby produce a stronger measurement signal. According to the embodiment shown, the second electrode 3 forms a single-ended lever which can be tilted about a tilt axis 8 at the lateral cavity boundary L. As shown, the second electrode 3 can be deflected directly at its capacitance measuring sections 15b while the capacitance measuring sections 15a of the first electrode 2 can be deflected via the double-ended lever over the tilt axis 8 so that an opposite movement can be generated. In the sixth embodiment, the coupling elements 7a, 7b are also designed as connecting elements 10 so that on the one hand, the coupling elements 7a, 7b connect the boundary layers 5a, 5b to one another and connect them to the first and second electrodes 2, 3.

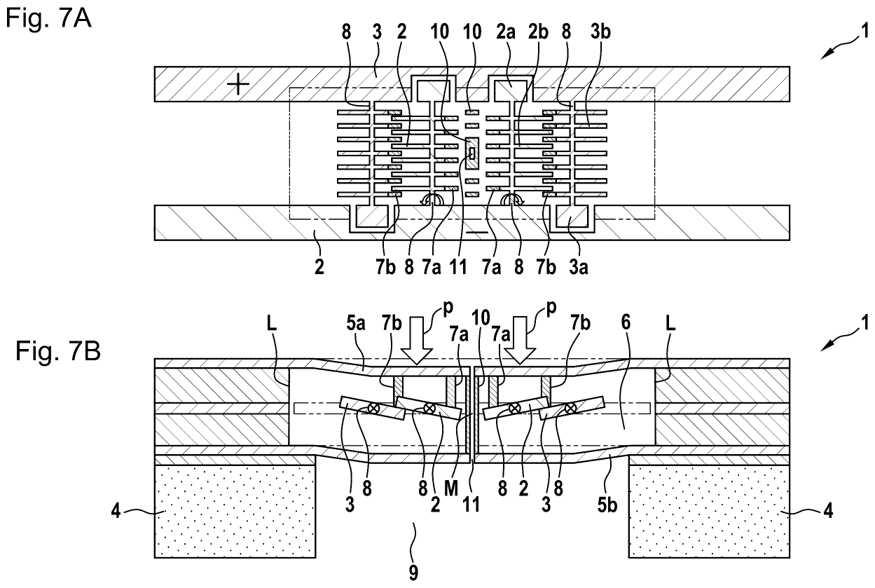

FIGS. 7A and 7B show a microelectromechanical device 1 according to a seventh embodiment. FIG. 7A shows a cross-sectional plan view and FIG. 7B a lateral cross-sectional view of the device 1 in a deflected state of the boundary layers 5a, 5b. In its basic structure and functional principle, the device 1 shown is comparable to the device 1 according to the sixth embodiment. However, while the device 1 according to the sixth embodiment shows continuous first and second electrodes 2, 3, the device 1 according to the seventh embodiment has segmented first and second electrodes 2, 3, that is to say the first and second electrodes 2, 3 have electrode sections that are spatially separated from one another and not directly connected to one another. This allows for improved use of area with short lever arms on the first and second electrodes 2, 3. According to the embodiment shown, the electrode sections separated from each other are each connected to the cavity boundary L of the device 1 via a torsion spring, which also forms a tilt axis 8 of each electrode section, and are coupled to the first boundary layer 5a by coupling elements 7a, 7b.

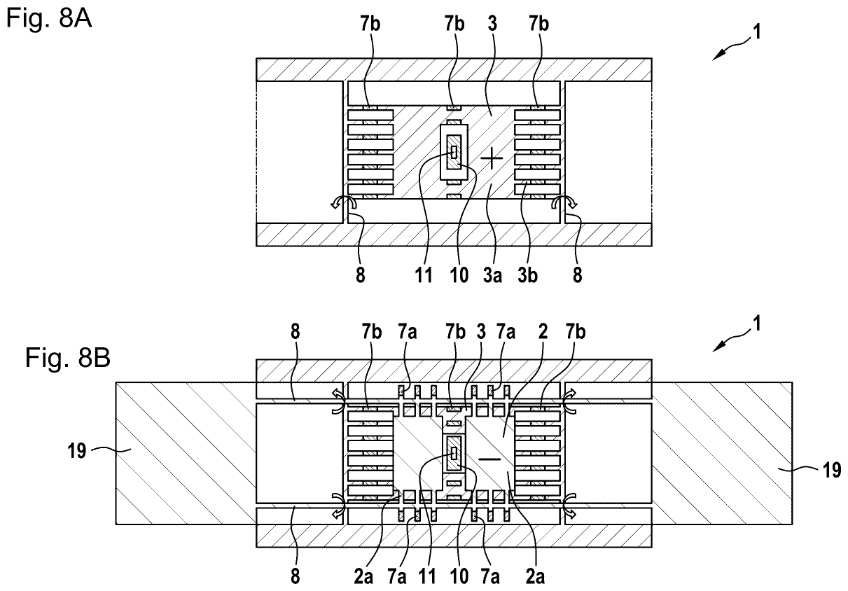

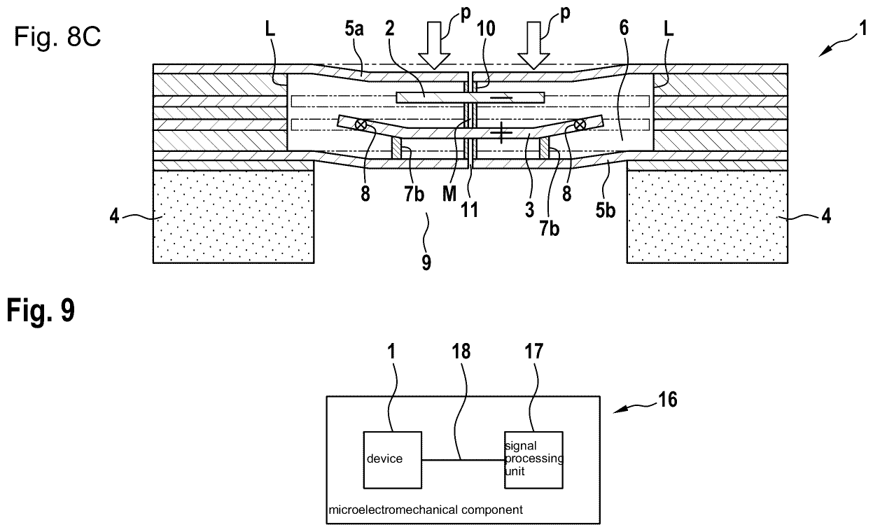

FIGS. 8A to 8C show a microelectromechanical device 1 according to an eighth embodiment. FIG. 8A shows a cross-sectional view in a first plane of the device, FIG. 8B shows a cross-sectional view in a second plane of the device 1, and FIG. 8C shows a lateral cross-sectional view of the device 1 in a deflected state of the boundary layers 5a, 5b. In this electrode arrangement, the first electrode 2 and the second electrode 3 are arranged in planes of the cavity 6 which lie on top of each other; for example, as shown, the first electrode 2 is arranged closer to the first boundary layer 5a, and the second electrode 3 is arranged closer to the second boundary layer 5b. The first and second electrodes 2, 3 have electrode base surfaces 2a, 3a which lie on top of each other and electrode bars 2b, 3b projecting therefrom which are each coupled via coupling elements 7a, 7b to at least one of the two boundary layers 5a, 5b and can be tilted about tilt axes 8. By tilting the electrode bars 2b, 3b of the electrodes 2, 3, a translational movement of the electrode base surfaces 2a, 3a relative to each other is effected so that a change in capacitance can be precisely measured.

FIG. 9 schematically shows a microelectromechanical component 16 with a device 1 according to the above-described features and a signal processing unit 17 which is connected to the device 1 by a signal connection 18 and is designed to apply and process signals of the microelectromechanical device 1. The micromechanical component 16 can be designed in particular as an absolute pressure sensor, and/or as a relative pressure sensor, and/or as a microphone. The microelectromechanical component 16 can, for example, be implemented as a system-on-chip.

What is claimed is:

1. A microelectromechanical device for capacitive fluid pressure measurement, the device comprising:
a first electrode;
a second electrode forming a counter-electrode; and
a cavity, formed between a first boundary layer and a second boundary layer or a substrate, in which the first electrode is arranged and movably mounted;
wherein the first boundary layer and/or the second boundary layer is deflectable by a fluid pressure, and wherein the first boundary layer and/or the second boundary layer is coupled to the first electrode by a first coupling element configured to transmit a deflection movement to the movably mounted first electrode.

2. The device according to claim 1, wherein the second electrode is arranged in the cavity.

3. The device according to claim 1, wherein the second electrode is movably mounted, and wherein the first boundary layer and/or the second boundary layer is coupled to the second electrode by a second coupling element configured to transmit a deflection movement to the second electrode.

4. The device according to claim 3, wherein the first coupling element and the second coupling element are arranged on the first electrode and the second electrode such that the first electrode and the second electrode are movable in opposite directions to each other.

5. The device according to claim 1, wherein the second electrode and/or a third electrode: (i) is arranged in or on the first boundary layer, and/or in or on the second boundary layer, or, (ii) is formed by the first boundary layer and/or the second boundary layer.

6. The device according to claim 1, wherein the first electrode and/or the second electrode is translationally displaceable at least sectionally by a deflection movement of the first boundary layer and/or the second boundary layer.

7. The device according to claim 1, wherein the first electrode and/or the second electrode can be tilted at least sectionally about a tilt axis by ae deflection movement of the first boundary layer and/or the second boundary layer.

8. The device according to claim 7, wherein the tilt axis is formed by a torsion spring.

9. The device according to claim 7, wherein the first electrode and/or the second electrode can be tilted about a plurality of tilt axes spaced apart from each other.

10. The device according to claim 1, wherein: (i) the first coupling element is arranged on a section of the first electrode facing a cavity center, and/or (ii) the second coupling element is arranged on a section of the second electrode facing the cavity center.

11. The device according to claim 1, wherein the cavity is formed between the first boundary layer and the second boundary layer, and wherein the second boundary layer spans a substrate recess introduced into a substrate of the device, wherein the first boundary layer and the second boundary layer are mechanically connected to one another by a connecting element in such a way that they can be deflected together by a fluid pressure acting on the first boundary layer and/or on the second boundary layer.

12. The device according to claim 11, wherein the device has a pressure equalization channel running through the first boundary layer and the second boundary layer and opening into the substrate recess.

13. The device according to claim 11, wherein the first electrode and/or the second electrode has a plurality of electrode bars extending substantially parallel to one another.

14. The device according to claim 13, wherein the electrode bars of the first electrode extend at least sectionally into gaps between the electrode bars of the second electrode.

15. The device according to claim 1, wherein the device has a plurality of first electrodes and/or one or more second electrodes that are arranged symmetrically in relation to a cavity center in the cavity.

16. The device according to claim 15, wherein the device has a rigid frame dividing the cavity into a plurality of segments, wherein the device includes a plurality of first electrodes, and wherein a first electrode of the plurality of first electrodes is arranged in each segment and is tiltable at least sectionally about a tilt axis defined by a torsion spring, wherein the torsion spring is connected to the rigid frame.

17. The device according to claim 16, wherein the second electrode and/or a third electrode: (i) is arranged in or on the first boundary layer and/or in or on the second boundary layer, or (ii) is formed by the first boundary layer and/or by the second boundary layer, and is segmented by one or more segment insulations such that an electrode segment of the second electrode and/or an electrode segment of the third electrode is assigned to a segment with a first electrode.

18. A microelectromechanical pressure sensor, comprising:
a microelectromechanical device, including:
a first electrode,
a second electrode forming a counter-electrode, and
a cavity, formed between a first boundary layer and a second boundary layer or a substrate, in which the first electrode is arranged and movably mounted,
wherein the first boundary layer and/or the second boundary layer is deflectable by a fluid pressure, and wherein the first boundary layer and/or the second boundary layer is coupled to the first electrode by a first coupling element configured to transmit a deflection movement to the movably mounted first electrode; and
a signal processing unit configured to apply and processing signals of the microelectromechanical device.

19. The microelectromechanical pressure sensor according to claim 18, wherein the micromechanical pressure sensor is an absolute or relative pressure sensor.

20. The microelectromechanical pressure sensor according to claim 18, wherein the micromechanical pressure sensor is a microelectromechanical microphone for capacitive sound pressure measurement.

21. The microelectromechanical pressure sensor according to claim 18, wherein the micromechanical pressure sensor is a microelectromechanical combination sensor element that includes a microphone for capacitive sound pressure measurement, and/or an absolute pressure sensor, and/or a relative pressure sensor.
